(19) United States
(12) Patent Application Publication
(10) Pub. No.: US 2016/0035915 A1
(43) Pub. Date: Feb. 4, 2016

(54) SEMICONDUCTOR SUBSTRATE AND METHOD FOR PRODUCING THE SAME, PHOTOVOLTAIC CELL ELEMENT, AND PHOTOVOLTAIC CELL

(71) Applicant: Hitachi Chemical Company, Ltd., Tokyo (JP)

(72) Inventors: Tetsuya SATO, Tsukuba-shi, (JP); Masato YOSHIDA, Tsukuba-shi (JP); Takeshi NOJIRI, Tsukuba-shi (JP); Yoichi MACHll, Tsukuba-shi (JP); Mitsunori IWAMURO, Tsukuba-shi (JP); Akihiro ORITA, Tsukuba-shi (JP)

(21) Appl. No.: 14/879,733

(22) Filed: Oct. 9, 2015

Related U.S. Application Data
(63) Continuation of application No. 13/557,188, filed on Jul. 24, 2012.
(60) Provisional application No. 61/511,252, filed on Jul. 25, 2011.
(60) Provisional application No. 61/511,258, filed on Jul. 25, 2011.
(60) Provisional application No. 61/511,272, filed on Jul. 25, 2011.

(30) Foreign Application Priority Data
Jul. 25, 2011 (JP) 2011-162645
Jul. 25, 2011 (JP) 2011-162646
Jul. 25, 2011 (JP) 2011-162647

(51) Int. Cl. H01L 31/0236; H01L 29/36; H01L 31/0224; H01L 21/225

(52) U.S. Cl. CPC H01L 31/02363; H01L 21/2255; H01L 29/36; H01L 31/022425

(57) ABSTRACT

The semiconductor substrate of the present invention contains a semiconductor layer and an impurity diffusion layer containing at least one impurity atom selected from the group consisting of an n-type imparity atom and a p-type impurity atom and at least one metallic atom selected from the group consisting of K, Na, Li, Ba, St, Ca, Mg, Be, Zn, Pb, Cd, V, Sn, Zr, Mo, La, Nb, Ta, Y, Ti, Ge, Te, and Lu.

### CROSS-REFERENCE TO RELATED APPLICATIONS

The present application is a continuation of U.S. patent application Ser. No. 13/557,188, filed Jul. 24, 2012, which, claims the benefit of U.S. provisional patent application No. 61/511,252, filed Jul. 25, 2011, U.S. provisional patent application No. 61/511,258, filed Jul. 25, 2011, and U.S. provisional patent application No. 61/511,272, filed Jul. 25, 2011, Japanese patent application number 2011-162647, filed Jul. 25, 2011, Japanese patent application number 2011-162646, filed Jul. 25, 2011, and Japanese patent application number 2011-162645, filed Jul. 25, 2011 the disclosures of which are incorporated herein by reference in their entirety.

### BACKGROUND OF THE INVENTION

1. Field of the Invention

The present invention relates to a semiconductor substrate and a method for producing the same, a photovoltaic cell element, and a photovoltaic cell.

2. Description of the Related Art

A related art fabrication process of an n-type diffusion layer of a silicon photovoltaic cell element is described below.

First, in order to realize high efficiency by promoting optical confinement effects, a p-type silicon substrate having a textured structure formed on a light receiving side is prepared, and subsequently subjected to a treatment at a temperature of 800° C. to 900° C. for several tens of minutes under a mixed gas atmosphere of phosphorus oxychloride (POCl₃), nitrogen and oxygen, thereby uniformly forming an n-type diffusion layer. According to this method of the related art, the surface of the silicon substrate is oxidized and an amorphous membrane of PSG (phosphosilicate glass) is formed. The only phosphorus atom diffuses to the silicon substrate and an n-type diffusion layer containing a phosphorus atom in high concentration is formed.

Meanwhile, in the field of manufacturing semiconductors, a method has been proposed for forming an n-type diffusion layer by applying a solution containing phosphates such as phosphorus pentoxide (P₂O₅) or ammonium dihydrogen phosphate (NH₄H₂PO₄) as a donor element-containing compound (see, for example, Japanese Patent Application Laid-Open (JP-A) No. 2002-75894). The method forms an n-type diffusion layer similarly to the above-mentioned gas-phase reaction method using a mixed gas. Furthermore, diffusion of phosphorus occurs at the side face and rear surface during either of the above-mentioned methods, and as n-type diffusion layer is formed not only on the surface, but also on the side face and the rear surface.

The n-type diffusion layer of the rear surface needs to be converted into a p⁺-type diffusion layer. Accordingly, an aluminum paste containing aluminum, which is a Group XIII element is applied to the n-type diffusion layer of the rear surface and then sintered to achieve conversion of the n-type diffusion layer into the p+-type diffusion layer and, in addition, formation of ohmic contact at the same time.

A method has been proposed to use a boron compound instead of an aluminum (see, for example, JP-A No. 2002-539615). Furthermore, a diffusion agent composition containing B₂O₃, Al₂O₃, or P₂O₅ dispersed in organic solvent has been proposed (see, for example, JP-A No. 2011-71489)

### SUMMARY OF THE INVENTION

A first embodiment according to the present invention is a semiconductor substrate, comprising:

a semiconductor layer; and

an impurity diffusion layer containing at least one impurity atom selected from the group consisting of an n-type Impurity atom and a p-type impurity atom, and containing at least one metallic atom selected from the group consisting of K, Na, Li, Ba, Sr, Ca, Mg, Be, Zn, Pb, Cd, V, Sn, Zr, Mo, La, Nb, Ta, V, Ti, Ge, Te, and Lu.

A second embodiment of the present invention is a photovoltaic cell element, comprising the semiconductor substrate of the first embodiment and an electrode disposed on the impurity diffusion layer.

A third embodiment of the present invention is a photovoltaic cell, comprising the photovoltaic cell element of the second embodiment and a wiring material disposed on the electrode.

A fourth embodiment of the present invention is a method of producing the semiconductor substrate of the first embodiment, the method comprising:

attaching an impurity diffusion layer-forming composition containing a glass powder containing at least one impurity atom selected from the group consisting of an n-type imparity atom and a p-type impurity atom, and a dispersion medium to at least one surface of a semiconductor layer; and

orming an impurity diffusion layer by subjecting the attached impurity diffusion layer-forming composition to thermal diffusion treatment.

The present invention enables to provide a semiconductor substrate which has excellent optical conversion efficiency and a method for producing the same, and a photovoltaic cell element and a photovoltaic cell using the semiconductor substrate.

### BRIEF DESCRIPTION OF THE DRAWINGS

FIG. 1 is a cross-sectional view conceptually showing an example of the manufacturing process of a photovoltaic cell element in the present invention,

FIG. 2A is a plane view of a photovoltaic cell element as seen from the front surface.

FIG. 2B is a partially enlarged, perspective view of a photovoltaic cell element shown in FIG. 2A.

### DETAILED DESCRIPTION OF THE INVENTION

As described above, in the formation of an n-type diffusion layer and a p⁺-type diffusion layer, a phosphorus atom or the like, which is an n-type impurity atom, and a boron atom or the like, which is a p-type impurity atom, replaces a silicon atom and diffuses into a silicon substrate. In particular, the atomic radii of phosphorus atoms and boron atoms are significantly smaller than the atomic radius of silicon atoms and these atoms may replace a silicon atom in high concentration. However replacement with a phosphorus atom or a boron atom may cause many lattice distortions (lattice defect) and the degree of plastic strain may increase. In a photovoltaic cell element, this defect causes recombination of carriers formed by light whereby the optical conversion property may be reduced.

Therefore, the present invention has been made in view of the above problems exhibited by the background art, and it is an object of the present invention to provide a semiconductor substrate which has excellent optical conversion efficiency and a method for producing the same, and a photovoltaic cell element and a photovoltaic cell using the semiconductor substrate.

The term “step” as used herein encompasses not only an independent step but also a step in which the anticipated effect of this step is achieved, even if the step cannot be clearly distinguished from another step. In addition, a numerical value range Indicated by use of the term “to” as used herein refers to a range including the numerical values described before and after “to” as the minimum and maximum values, respectively. Unless specifically indicated, in a case in which each ingredient of a composition includes plural materials, the content of each ingredient of the composition denotes the total amount of the plural materials included in the composition.

The invention includes the following embodiments.
<1> A semiconductor substrate, including:

a semiconductor layer; and

an impurity diffusion layer containing at least one impurity atom selected from die group consisting of an n-type impurity atom and a p-type Impurity atom, and containing at least one metallic atom selected from the group consisting of K, Na, Li, Ba, Sr, Ca, Mg, Be, Zn, Pb, Cd, V, Sn, Zr, Mo, La, Nb, Ta, Y, Ti, Ge, Te, and Lu.
<2> The semiconductor substrate according to <1>, wherein the content of the metallic atom at a surface of the Impurity diffusion layer is 1×10¹⁷ atoms/cm³ or mom.
<3> The semiconductor substrate according to <1> or <2>, wherein the n-type Impurity atom is at least one selected from P (phosphorus) or Sb (antimony).
<4> The semiconductor substrate according to <1> or <2>, wherein the p-type impurity atom is at least one selected from B (boron) or Ga (gallium).
<5> The semiconductor substrate according to any one of <1> to <3>, wherein the Impurity diffusion layer contains the retype impurity atom and is formed by subjecting a glass powder to heat treatment, the glass powder being attached to at least one surface of the semiconductor layer, and the glass powder containing a substance including at least one kind of n-type impurity selected morn P₂O₃, P₂O₅ or Sb₂O₃, and containing at least one kind of glass component material selected from SiO₂, K₂O, Na₂O, Li₂O, BaO, SrO, CaO, MgO, BeO, ZnO, PbO, CdO, V₂O₅, SnO, ZrO₂, or MoO₃.
<6> The semiconductor substrate to any one of <1>, <2>, and <4>, wherein the impurity diffusion layer contains the p-type impurity and is formed by subjecting a glass powder to heat treatment, the glass powder being attached to at least one surface of the semiconductor layer, and the glass powder containing a substance including at least one kind of p-type impurity selected from B₂O₃ or Ga₂O₃, and including at least one kind of glass component material selected from SiO₂, K₂O, Na₂O, Li₂O, BaO, SrO, CaO, MgO, BeO, ZnO, PbO, CdO, V₂O₅, SnO, ZrO₂, or MoO₃.
<7> A photovoltaic cell element, comprising the semiconductor substrate according to any one of <2> to <6> and an electrode disposed on the impurity diffusion layer.
<8> A photovoltaic cell comprising the photovoltaic cell element according to <7> and a wiring material disposed on the electrode.
<9> A method of producing the semiconductor substrate according to any one of <1> to <6>, the method including:

attaching an impurity diffusion layer-forming composition containing a glass powder containing at least one impurity atom selected from the group consisting of an n-type impurity atom and a p-type impurity atom, and a dispersion medium to at least one surface of a semiconductor layer; and

forming an impurity diffusion layer by subjecting the attached, impurity diffusion layer-forming composition to thermal diffusion treatment.

### <Semiconductor Substrate>

The semiconductor substrate of the present invention includes a semiconductor layer and an impurity diffusion layer containing at least one impurity atom selected from the group consisting of an n-type impurity atom and a p-type impurity atom, and containing at least one metal atom selected from the group consisting of K, Na, Li, Ba, Sr, Ca, Mg, Be, Zn, Pb, Cd, V, Sn, Zr, Mo, La, Nb, Ta, Y, Ti, Ge, Te, and Lu (hereinafter, also referred to as “specific metal atom group”). By containing at least one metal atom selected from the specific metal atom group in the impurity diffusion layer, a semiconductor substrate having an excellent optical conversion efficiency can be configured. It can be thought that the semiconductor substrate can demonstrate an excellent optical conversion characteristics due to, for example, relaxation of distortion in the impurity diffusion layer.

Still further, for the purpose of obtaining a high efficiency, a photovoltaic cell element is now being developed which has a so-called selective emitter structure in which two types of impurity diffusion layers having different impurity concentrations are provided and an electrode is formed on the impurity diffusion layer having the higher impurity concentration, and has a back-contact structure in which both an n-type and p-type diffusion layer are formed on back surface. In this case, when two types of impurity diffusion layers having different concentrations are formed by a conventional method, it is difficult to identify a region where an imparity diffusion layer is formed. For this reason, it becomes difficult to adjust the position of the electrode to be formed on the impurity diffusion layer having the higher impurity concentration and on the two types of impurity diffusion consisting of an n-type and a p-type on the same surface, winch sometimes results in deterioration hi the characteristics of the photovoltaic cell element.

in the semiconductor substrate of the present invention, however, it becomes possible to identify the region where an impurity diffusion layer is formed when the impurity diffusion layer contains at least one metal atom selected from the specific metal atom group (hereinafter, also simply referred to as “specific metal atom”). Accordingly, an electrode cart be easily formed on the impurity diffusion layer of the semiconductor substrate with an excellent precision in adjusting the position of the electrode. That is, by using the semiconductor substrate, a photovoltaic cell element having a selective emitter structure and a photovoltaic cell element having a back-contact structure can be efficiently manufactured without causing deterioration in the characteristics thereof.

The semiconductor layer may be a p-type semiconductor layer or an n-type semiconductor layer. Among these, the p-type semiconductor layer is preferred and a p-type silicon layer is more preferred.

The impurity diffusion layer of the semiconductor substrate contains at least one metal atom selected from the specific metal atom group and, from the aspect of relaxation of distortion and the identifiability, preferably contains at least one metal atom selected from the group consisting of K, Na, Li, Ba, Sr, Ca, Mg, Zn, Pb, Cd, V, Sn, Zr, Mo, La, Nb, Ta, Y, Ti, Ge, Te, and Lu more preferably contains at least one metal atom selected from the group consisting of K, Na, Li, Ba, Ca, Mg, Zn, Sn, Ti, Te, V and Pb and still more preferably contains at least one metal atom selected from the group consisting of Ca and Mg.

The content of the specific metal atom contained in the impurity diffusion layer is not particularly restricted as long as the effect of the present invention is obtained. From the aspect of, among others, relaxation, of distortion and the identifiability, the content of the surface of the impurity diffusion layer is preferably 1×10¹⁷ atoms/cm³ or higher and more preferably is 1×10¹⁷ atoms/cm³ to 1×10²⁰ atoms/cm³.

The type and the content of the specific metal atom in the impurity diffusion layer can be measured by conducting a secondary ion mass spectrometry (SIMS analysis) by a conventional method using IMS-7F (manufactured by CAMECA CO., LTD.),

Concretely, a predetermined area of a region to be measured is subjected to the secondary ion mass spectrometry while being scraped in the depth direction, to determine the type and the concentration of the specific metal atom. It is noted that the content of the specific metal atom at the surface is the specific metal atom concentration measured at the time when a depth of 0.025 μm is attained after the beginning of the measurement from the surface.

The semiconductor substrate can be manufactured, for example, in the below-described manufacturing method of a semiconductor substrate.

### [Manufacturing Method of Semiconductor Substrate]

A manufacturing method of a semiconductor substrate of the present invention is configured to include a step of providing on at least one surface of a semiconductor layer with an impurity diffusion layer forming composition containing a glass powder including at least one impurity atom selected from the group consisting of n-type impurity atom and a p-type impurity atom, and a dispersion medium, a step of forming an impurity diffusion layer by allowing the provided impurity diffusion layer forming composition to a thermal diffusion treatment and, as needed, other steps.

In the manufacturing method of a semiconductor substrate, a glass powder (hereinafter, occasionally simply referred to as “glass powder”) containing at least one impurity atom selected from the group consisting of an n-type impurity atom (hereinafter, also referred to as “donor element”) and a p-type impurity atom (hereinafter, also referred to as “acceptor element”), and an impurity diffusion layer forming composition containing a dispersion medium. The impurity diffusion layer forming composition may further contain other additives as needed in consideration of the coating properties or the like.

As used herein, the term “impurity diffusion layer composition” refers to a material which contains at least one impurity atom selected from the group consisting of an n-type impurity atom and a p-type impurity atom and is capable of forming an impurity diffusion layer through thermal diffusion of the these impurity element after application of the material to a semiconductor substrate. In a case the composition for tanning an n-type diffusion layer according to the present invention is applied, a side etching process essential in the conventionally widely used gas-phase reaction method becomes unnecessary; consequently the process is simplified. In addition, for example in a case an n-type diffusion layer farms on a p-type semiconductor substrate using gas-phase reaction method, a process for converting an n-type diffusion layer formed on the rear surface into a p⁺-type diffusion layer becomes unnecessary. For these reasons, a method of forming a p⁺-type diffusion layer on the rear surface and the constituent material, shape and thickness of a rear surface electrode are not limited, and the range of applicable producing methods, constituent materials and shapes is widened. In a case of applying a p-type impurity diffusion, layer forming composition to form a p⁺-type diffusion layer, the occurrence of internal stress in a silicon substrate due to the thickness of the rear surface electrode is suppressed; consequently warpage of the silicon substrate is also suppressed.

Further, a glass powder contained in the impurity diffusion layer forming composition in accordance with the present invention is melted by means of sintering to form a glass layer over an impurity diffusion layer. However, a conventional gas-phase reaction method or a conventional method of applying a phosphate-containing solution or paste also forms a glass layer over an impurity diffusion layer, and therefore the glass layer formed in the present invention can be removed by etching, similarly to the conventional method. Accordingly, even when compared with the conventional method, the method using the impurity diffusion layer forming composition generates no unnecessary products and no further additional processes.

Further, since an impurity atom in the glass powder is hardly volatilized even during sintering, an impurity diffusion layer is prevented from also being formed on the rear surface or side face, rather than on the front surface alone due to the generation of volatile gases. It is assumed that the reason for this is that the impurity atom combines with an element in a glass powder, or is absorbed into the glass, as a result of which the impurity atom is hardly volatilized.

As described above, since the impurity diffusion layer forming composition can form an impurity diffusion, layer in a desired portion at a desired concentration, it is possible to form a selective region with a high impurity concentration. Meanwhile, it is difficult to form a selective region having a high impurity concentration by a conventional method such as a method using a gas-phase reaction or a method using a solution containing phosphates or borate salt.

The glass powder containing at least one impurity atom selected from the group consisting of an n-type impurity atom and a p-type impurity atom will be described in more detail.

The impurity atom-containing glass powder preferably includes an impurity atom-containing material, the specific metal atom-containing materials and an other glass component material if necessary. Herein, the glass component material may be a material containing the specific metal atom.

The term “n-type impurity atom” refers to an element which is capable of forming an n-type diffusion layer by diffusing (doping) thereof on a semiconductor substrate. As the n-type impurity atom, elements of Group XV of the periodic table can be used. Examples of the donor element include P (phosphorous), Sb (antimony), Bi (bismuth) and As (arsenic). From the aspect of safety, convenience of vitrification or the like, P or Sb is preferable.

Examples of the n-type impurity atom-containing material which is used for introducing the n-type impurity atom bate the glass powder include P₂O₃, P₂O₅, Sb₂O₃, Bi₂O₃, and As₂O₃. At least one selected from P₂O₃, P₂O₅ and Sb₂O₃ is preferably used.

The term “p-type impurity atom” refers to an element which is capable of forming an p-type diffusion layer by diffusing (doping) thereof on a semiconductor substrate. As the p-type impurity atom, elements of Group XIII of the periodic table can. be used. Examples of the donor element include B (boron), Al (aluminum) and Ga (gallium).

Examples of the p-type impurity atom-containing material which is used for introducing the p-type impurity atom into the glass powder include B₂O₃, Al₂O₃ and Ga₂O₃. At least one selected from B₂O₃, Al₂O₃ and Ga₂O₃ is preferably used.arsenic). From the aspect of safety, convenience of vitrification or the like, P or Sb is preferable.

The glass powder preferably contains, in addition to the n-type impurity-containing material, at least one material containing specific metal atom selected from the group consisting of K, Na, Li, Ba, Sr, Ca, Mg, Be, Zn, Pb, Cd, V, Sn, Zr, Mo, La, Nb, Ta, Y, Ti, Zr, Ge, Te and Lu. Examples of the material containing the specific metal atom include K₂O, Na₂O, Li₂O, BaO, SrO, CaO, MgO, BeO, ZnO, PbO, CdO, V₂O₅, SnO, ZrO₂, MoO₃, La₂O₃, Nb₂O₅, Ta₂O₅, Y₂O₃, TiO₂, ZrO₂, GeO₂, TeO₂ and Lu₂O₃.

As the specific metal atom, those having a large atomic radius is preferably selected when, like in the case of a phosphorous atom, the n-type impurity atom has a smaller atomic radius than that of a silicon atom. By selecting a specific metal atom having a large atomic radius, lattice distortion occurred in the n-type diffusion layer can be effectively relaxed.

The content ratio of a material containing a specific metal atom in the glass powder is not particularly restricted. Generally, the content ratio is preferably from 0.1% by mass to 95% by mass, and more preferably from 0.5% by mass to 90% by mass.

Further, the melting temperature, softening point, glass-transition point chemical durability or the like of the glass powder can be controlled by adjusting the component ratio, if necessary. Further, the glass powder preferably contains the glass components material mentioned below.

Examples of the glass component material include SiO₂, K₂O, Na₂O, Li₂O, BaO, SrO, CaO, MgO, BeO, ZnO, PbO, CdO, V₂O₅, SnO, ZrO₂, WO₃, MnO₃, MnO, La₂O₃, Nb₂O₅, Ta₂O₅, Y₂O₃, TiO₂, ZrO₂, GeO₂, TeO₂, and Lu₂O₃. At least one selected from these glass component material is preferably used.

The glass powder preferably does not contain a heavy metal atom which is a killer element accelerating recoupling of a carrier in a semiconductor substrate, a p-type impurity atom in a case of n-type diffusion layer forming composition, or n p-type impurity atom ha a case of p-type diffusion layer forming composition. Examples of the heavy metal, atom which is a killer element include Fe, Co, Ni, Mn, W, Cu, Cr and the like. Examples of the p-type impurity atom include the Group XIII if elements and examples of the n-type impurity atom include the Group XV elements.

Specific examples of the n-type impurity-containing glass powder include materials including both the n-type impurity atom-containing material and the glass component material, for example, P₂O₅ based glass which includes P₂O₅ as the n-type impurity-containing material such as P₂O₅—K₂O based glass, P₂O₅—Na₂O based glass, P₂O₅—Li₂O based glass, P₂O₅—BaO based glass, P₂O₅—SrO based glass, P₂O₅—CaO based glass, P₂O₅—MgO based glass, P₂O₅—BeO based glass, P₂O₅—ZnO based glass, P₂O₅—CdO based glass, P₂O₅—PbO based glass, P₂O₅—V₂O₅ based glass, P₂O₅—SnO based glass, P₂O₅—GeO₂ based glass, and P₂O₅—TeO₂ based glass; Sb₂O₃ based glass in which P₂O₅ is replaced by Sb₂O₃ as a n-type impurity-containing material in the P₂O₅based glass.

Although composite glass containing two components was illustrated in the above, composite glass containing three or more components, such as P₂O₅—SiO₂—CaO or P₂O₅—SiO₂MgO, may also be possible.

Specific examples of the p-type impurity-containing glass powder include those including both the p-type impurity-containing material and the glass component material such as, for example, B₂O₃ based glass which includes B₂O₃ as the p-type impurity-containing material such as B₂O₃—SiO₂ based glass, B₂O₃—ZnO based glass, B₂O₃—PbO based glass, single B₂O₃ based glass; Al₂O₃ based glass which includes Al₂O₃ as the p-type impurity-containing material such as Al₂O₃—SiO₂ based glass.

Although composite glasses containing one or two components are illustrated in the above, composite glass containing three or more components, such as B₂O₃SiO₂—Na₂O, may also be possible.

The content of the glass component material in the glass powder is preferably appropriately set taking into consideration the melting temperature, the softening point, the glass-transition point, and chemical durability. Generally, the content of the glass component material is preferably from 0.1% by mass to 95% by mass, and more preferably from 0.5% by mass to 90% by mass.

The softening point of the glass powder is preferably in the range of from 200° C. to 1000° C., and more preferably from 300° C. to 900° C., from the aspect of diffusivity during foe diffusion treatment, and dripping.

The shape of the glass powder includes a substantially spherical shape, a flat shape, a block shape, a plate shape, a scale-like shape, and the like. From the aspect of the coating property and uniform dispersion property, it is preferably a spherical shape, a flat shape, or a plate shape.

The mean particle diameter of the glass powder is preferably 100 μm or less. In a case a glass powder having a mean particle diameter of 100 μm or less is used, a smooth coated film can be easily obtained. Further, the mean particle diameter of the glass powder is more preferably 50 μm or less. The lower limit of the particle diameter is not particularly limited, and preferably 0.01 μm or more.

The mean particle diameter of the glass powder means the average volume particle diameter, and may be measured by laser diffraction particle size analyzer.

The impurity atom-containing glass powder is prepared according to the following procedure.

First, raw materials, for example, the impurity-containing material and the glass component material are weighed and placed in a crucible. Examples of the material for the crucible include platinum, platinum-rhodium, iridium, alumina, quartz and carbon, which are appropriately selected taking into consideration the melting temperature, atmosphere, reactivity with melted materials, and the like.

Next, the raw materials are heated to a temperature corresponding to the glass composition in an electric furnace, thereby preparing a solution. At this time, stirring is preferably applied such that the solution becomes homogenous.

Subsequently, the obtained solution is allowed to flow on a zirconia substrate, a carbon substrate or the like to result in vitrification of the solution.

Finally, the glass is pulverized into a powder. The pulverization can be carried out by using a known method such as using a jet mill, bead mill or ball mill.

The content of the impurity atom-con taming glass powder in the impurity diffusion layer forming composition is determined taking into consideration coatability, diffusivity of donor elements, and the like. Generally, the content of the glass powder in the impurity diffusion layer forming composition is preferably from 0.1% by mass to 95% by mass, more preferably from 1% by mass to 90% by mass, still more preferably from 1.5% by mass to 85% by mass, and furthermore preferably from 2% by mass to 80% by mass.

Hereinafter a dispersion medium will be described.

The dispersion medium is a medium which disperses the glass powder in the impurity diffusion layer forming composition. Specifically, a binder, a solvent or the like is employed as the dispersion medium.

For example, the binder may be appropriately selected from a polyvinyl alcohol, polyacrylamide resins, polyvinyl amide resins, polyvinyl pyrrolidone resins, polyethylene oxide resins, polysulfonic acid resins, acrylamide alkyl sulfonic acid resins, cellulose ether and cellulose derivatives such as carboxymethylcellulose, hydroxyethylcellulose, ethylcelluloses gelatin, starch and starch derivatives, sodium alginates and its derivatives, xanthane and xanthane derivatives, guar and guar derivatives, scieroglucan and scieroglucan derivatives, tragacanth arid tragacanth derivatives, dextrin and dextrin derivatives, (meth)acrylic acid resins, (meth)acrylic acid ester resins (for example, alkyl (meth)acrylate resins, dimethlaminoethyl (meth)acrylate resins, or the like), butadiene resins, styrene resins, and copolymers thereof, siloxane resins, and the like. These compounds may be used individually or in a combination of two or more thereof.

The molecular weight of the binder is nor particularly restricted, and is desired to be adjusted appropriately in view of the desired viscosity as the composition. For example, the weight-average molecular weight can be 10,000 to 500,000, and is preferably 50,000 to 300,000.

The content ratio of the binder in the impurity diffusion layer forming composition is not particularly restricted and can be appropriately adjusted in view of the desired viscosity as the composition or the discharge performance in an ink-jet method. For example, the content ratio of the binder in the impurity diffusion layer forming composition can be 0.5% by mass to 10% by mass and is preferably 2% by mass to 8% by mass.

Examples of the solvent include ketone solvents such as acetone, methylethylketone, methyl-n-propylketone, methyl-isopropylketone, methyl-n-butylketone, methyl-isobutylketone, methyl-n-pentylketone, methyl-n-hexylketone, diethylketone, dipropylketone, di-isobutylketone, trimethylnonanone, cyclohexanone, cyclopentanone, methylcyclohexanone, 2,4-pentanedione, acetonylacetone, γ-butyrolactone, and γ-valerolactone; ether solvents such as diethyl ether, methyl ethyl ether, methyl-n-propyl ether, di-isopropyl ether, tetrahydrofuran, methyl tetrahydrofuran, dioxane, dimethyl dioxane, ethylene glycol dimethyl ether, ethylene glycol diethyl ether, ethylene glycol di-n-propyl ether, ethylene glycol dibutyl ether, diethylene glycol dimethyl ether, diethylene glycol diethyl ether, diethylene glycol methyl ethyl ether, diethylene glycol methyl mono-n-propyl ether, diethylene glycol methyl mono-n-butyl ether, diethylene glycol di-n-propyl ether, diethylene glycol di-n-butyl ether, diethylene glycol methyl mono-n-hexyl ether, triethylene glycol dimethyl ether, triethylene glycol diethyl ether, triethylene glycol methyl ethyl ether, triethylene glycol methyl mono-n-butyl ether, triethylene glycol di-n-butyl ether, triethylene glycol methyl mono-n-hexyl ether, tetraethylene glycol dimethyl ether, tetraethylene glycol diethyl ether, tetradiethylene glycol methyl ethyl ether, tetraethylene glycol methyl mono-n-butyl ether, diethylene glycol di-n-butyl ether, tetraethylene glycol methyl mono-n-hexyl ether, tetraethylene glycol di-n-butyl ether, propylene glycol dimethyl ether, propylene glycol diethyl ether, propylene glycol, di-n-propyl ether, propylene glycol dibutyl ether, dipropylene glycol dimethyl ether, dipropylene glycol diethyl ether, dipropylene glycol methyl ethyl ether, dipropylene glycol methyl mono-n-butyl ether, dipropylene glycol di-n-propyl ether, dipropylene glycol dimethyl ether, dipropylene glycol, methyl mono-n-hexyl ether, tripropylene glycol dimethyl ether, tripropylene glycol diethyl ether, tripropylene glycol methyl ethyl ether, tripropylene glycol methyl mono-n-butyl ether, tripropylene glycol di-n-butyl ether, tripropylene glycol methyl mono-n-hexyl ether, tetrapropylene glycol dimethyl ether, tetrapropylene glycol diethyl, ether, tetradipropylene glycol, methyl ethyl ether, tetrapropylene glycol methyl mono-n-butyl ether, dipropylene glycol di-n-butyl ether, tetrapropylene glycol methyl mono-n-hexyl ether, and tetrapropylene glycol di-n-butyl ether; ester solvents such as methyl acetate, ethyl acetate, n-propyl acetate, isopropyl acetate, n-butyl acetate, isobutyl acetate, sec-butyl acetate, n-pentyl acetate, sec-pentyl acetate, 3-methoxybutyl acetate, methyl pentyl acetate, 2-ethyl butyl acetate, 2-ethyl hexyl acetate, 2-(2-butoxyethoxy)ethyl acetate, benzyl acetate, cyclohexyl acetate, methyl cyclohexyl acetate, nonyl acetate, methyl acetoacetate, ethyl acetoacetate, diethylene glycol monomethyl ether acetate, diethylene glycol monoethyl ether acetate, diethylene glycol mono-n-butyl ether acetate, dipropylene glycol monomethyl ether acetate, dipropylene glycol monoethyl ether acetate, glycol diacetate, methoxy triglycol acetate, ethyl propionate, n-butyl propionate, isoamyl propionate, diethyl oxalate, di-n-butyl oxalate, methyl lactate, ethyl lactate, n-butyl lactate, and n-amyl lactate; ether acetate solvents such as ethylene glycol methyl ether propionate, ethylene glycol ethyl ether propionate, ethylene glycol methyl ether acetate, ethylene glycol ethyl ether acetate, diethylene glycol methyl ether acetate, diethylene glycol ethyl ether acetate, diethylene glycol-n-butyl ether acetate, propylene glycol methyl ether acetate, propylene glycol ethyl ether acetate, propylene glycol propyl ether acetate, dipropylene glycol methyl ether acetate, and dipropylene glycol ethyl ether acetate; aprotic polar solvents such as acetonitrile, N-methyl pyrrolidinone, N-ethyl pyrrolidinone, N-propyl pyrrolidinone, N-butyl pyrrolidinone, N-hexyl pyrrolidinone, N-cyclohexyl pyrrolidinone, N,N-dimethyl formamide, N,N-dimethyl acetamide, and dimethyl sulfoxide; alcohol solvents such as methanol, ethanol, n-propanol, isopropanol, n-butanol, isobutanol, sec-butanol, tert-butanol, n-pentanol, isopentanol, 2-methylbutanol, sec-pentanol, tert-pentanol, 3-methoxy butanol, n-hexanol, 2-methylpentanol, sec-hexanol, 2-ethylbutanol, sec-heptanol, n-octanol, 2-ethylhexanol, sec-octanol, n-nonyl alcohol, n-decanol, sec-undecyl alcohol, trimethylnonyl alcohol, sec-tetradecyl alcohol, sec-heptadecyl alcohol, phenol, cyclohexanol, methylcyclohexanol, benzyl alcohol, ethylene glycol, 1,2-propylene glycol, 1,3-butylene glycol, diethylene glycol, dipropylene glycol, triethylene glycol, and tripropylene glycol; glycol monoether solvents such as ethylene glycol methyl ether, ethylene glycol ethyl ether, ethylene glycol, monophenyl ether, diethylene glycol monomethyl ether, diethylene glycol monoethyl ether, diethylene glycol mono-n-butyl ether, diethylene glycol mono-n-hexyl ether, ethoxy triglycol, tetraethylene glycol mono-n-butyl ether, propylene glycol monomethyl ether, dipropylene glycol monomethyl ether, dipropylene glycol monoethyl ether, and tripropylene glycol monomethyl ether; terpene solvents such as α-terpinene, α-terpinenol, myrcene, allo-ocimene, imonene, dipentene, α-dipentene, β-dipentene, terpinenol, carvone, ocimene and phellandrene; water, and the like. These solvents may be used individually or in a combination of two or more thereof. From the aspect of the coating property of the impurity diffusion layer forming composition at a substrate, at least one selected from the group consisting of α-terpinenol, diethylene glycol mono-n-butyl ether and 2-(2-butoxyethoxy)ethyl acetate is more preferable.

The content of the dispersion medium in the impurity diffusion layer forming composition is determined taking into consideration coatability and donor concentration.

The viscosity of the impurity diffusion layer forming composition is preferably from 10 mPa·s to 1,000,000 mPa·s and mom preferably from 50 mPa·s to 500,000 mPa·s in consideration of the coating properties.

Further, the impurity diffusion layer forming composition may further contain other additives. Examples of the other additives include a surfactant, a metal particle such as silicon and a thickener.

Examples of the thickener include the same binders as the above-mentioned binders. When a thickener is contained, the content ratio of the thickener can be appropriately selected such that, for example, the viscosity as the impurity diffusion layer forming composition is from 20 Pa·s to 1,000 Pa·s.

By containing a thickener such that the viscosity as the impurity diffusion layer forming composition is in the above-mentioned range, ease of provision of the composition on a semiconductor layer improves and as the result, for example, an excellent reproduction of thin lines is obtained.

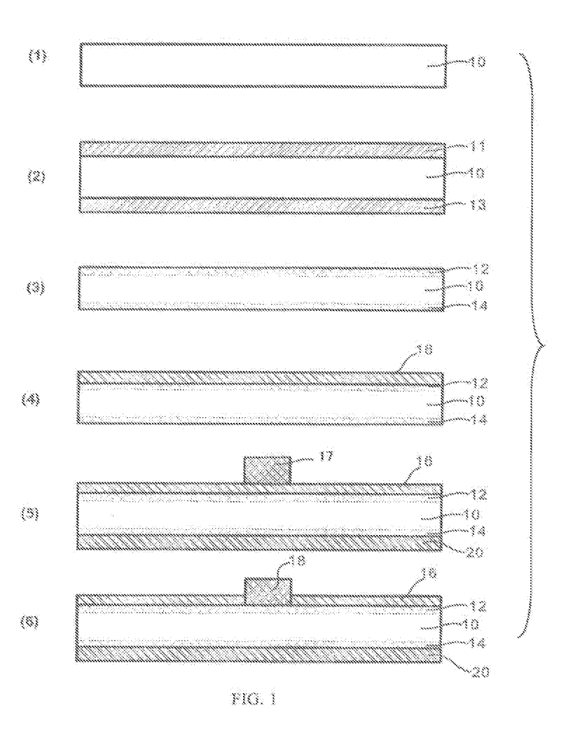

Hereinafter, as specific examples of the method for producing a semiconductor substrate according to the present invention, the method for producing a photovoltaic cell element described with reference to FIG. 1. FIG. 1 is a schematic cross-sectional view conceptionally showing an example of the production process of a photovoltaic cell according to the present invention. In the drawings, like numbers refer to like elements throughout the specification.

In FIG. 1(1), an alkaline solution is assigned to silicon substrate which is a p-type semiconductor substrate 10, thereby removing the damaged layer, and a textured structure is obtained by etching.

Specifically, the damaged layer of the silicon surface, which is caused when being sliced from an ingot, is removed by using 20% by mass of caustic soda. Then, a textured structure is formed by etching with a mixture of 1% by mass of caustic soda and 10% by mass of isopropyl alcohol (in the drawing, the textured structure is omitted). The photovoltaic cell achieves high efficiency through the formation of a textured structure on the light-receiving side (front surface) to promote optical confinement effects.

In FIG. 1(2), the n-type diffusion, layer forming composition as the impurity diffusion layer forming composition, is applied on the surface of the p-type semiconductor substrate 10, that is, a face serving as a light-receiving side, thereby forming an n-type diffusion layer-forming composition layer 11. In the present invention, there is no limit to the application method, for example, a printing method, a spinning method, brush application, a spray method, a doctor blade method, a roll-coater method, an inkjet method or the like can be used.

The amount of coating of the n-type diffusion layer forming composition for is not particularly limited, but is in the range of from 0.01 g/m² to 100 g/m² in terms of glass powder, and preferably from 0.1 g/m² to 10 g/m².

nge of from 0.01 to 100 g/m² in terms of glass powder, and preferably from 0.1 to 10 g/m².

Further, depending on the composition of the impurity diffusion layer forming composition, a drying process for volatilization of the solvent contained in the composition may be required after the application thereof if necessary. In this case, the drying is carried out at a temperature of 80° C. to 300° C., for 1 minute to 10 minutes when using a hot plate, or for 10 minutes to 30 minutes when using a dryer or the like. Since these drying conditions are dependent on the solvent composition of the impurity diffusion layer forming composition, the present invention is not particularly limited to the above-stated conditions.

Further, the p-type semiconductor substrate on which the n-type diffusion layer forming composition is applied is preferably subjected to a thermal treatment, for example, at 200° C. to 800° C. under an atmosphere containing oxygen or allowing a gas containing oxygen to flow (for example, allowing air to flow). The temperature of the thermal treatment is preferably 300° C. to 800° C., more preferably 400° C. to 700° C. and still more preferably 400° C. to 600° C. By this thermal treatment, most of dispersion medium (preferably binder) can be removed, whereby an n-type diffusion layer having a good characteristics cart be formed.

The thermal treatment time is not particularly restricted and can be appropriately selected depending on the configuration of the n-type diffusion layer forming composition or the like. For example, the time can be 1 minute to 30 minutes.

In a case using the producing method of the present invention, a producing method of a p⁺-type diffusion layer (high-density electric field layer) 14 of the rear surface can employ any conventional known method without being limited to the method involving conversion of an n-type diffusion layer into a p⁺-type diffusion layer using aluminum, and the range of choices for the producing method is then widened. Accordingly, for example, by applying the composition 13 containing an element of Group XIII of the periodic table which is an impurity diffusion layer forming composition, the p⁺-type diffusion layer (high-density electric field layer) 14 can be formed.

The method for applying a p-type diffusion forming composition 13 to the rear side of the p-type semiconductor substrate is the same manner as the method for applying the n-type diffusion layer forming composition, to the p-type semiconductor substrate as described above.

The p-type diffusion forming composition 13 applied to the rear side is subjected to thermal diffusion treatment in the same manner as when the n-type diffusion layer forming composition 11 is used, thereby forming the a p-type diffusion layer (high-density electric field layer) 14 on the rear side. The thermal diffusion treatment of the p-type diffusion layer forming composition is preferably simultaneously conducted with the thermal diffusion treatment of the n-type diffusion layer forming composition.

Next, the p-type semiconductor substrate 10, on which the n-type diffusion layer-forming composition layer 11 was formed, is subjected to a thermal diffusion treatment at a temperature of 600 to 1200° C. This thermal diffusion, treatment results in diffusion of a donor element into the p-type semiconductor substrate, thereby forming an n-type diffusion layer 12, as shown in FIG 1(3). At this point the specific metal atom contained in the n-type diffusion layer forming composition 11 diffuses into the n-type diffusion layer 12. This relaxes lattice distortion due to plastic deformation occurred in the region where the n-type impurity atom (for example, a phosphorous atom) is diffused in high concentration, thereby inhibiting the occurrence of a defect.

The specific metal atom diffused in the n-type diffusion layer is preferably contained in a concentration range of 1×10¹⁷ atoms/cm³ or higher at the surface of the n-type diffusion layer. From the aspect that diffusion of the n-type impurity atom is inhibited by decreasing the lattice defect, the concentration is more preferably in a range of 1×10¹⁷ atoms/cm³ to 1×10²⁰ atoms/cm³ so that the concentration does not become too high.

The thermal diffusion treatment can be carried out using a known continuous furnace, batch furnace, or the like. In addition, when performing the thermal diffusion treatment, the furnace atmosphere can be appropriately adjusted with ah; oxygen, nitrogen, or the like.

The treatment time of the thermal diffusion can be appropriately selected depending on the content of a donor element contained in the n-type diffusion layer forming composition. For example, the treatment time of the thermal diffusion may be in the range of from 1 minute to 60 minutes, and preferably from 2 minutes to 30 minutes.

Since a glass layer (not shown) made of phosphoric acid glass or the like is formed on the surface of the formed n-type diffusion layer 12, the phosphoric acid glass is removed by etching. The etching can be carried out by using a known method, including a method of dipping a subject in an acid, such as hydrofluoric acid, a method of dipping a subject in an alkali, such as caustic soda, or the like.

As shown in FIGS. 1(2) and 1(3), the n-type diffusion layer-forming method for forming an n-type diffusion layer 12 using the n-type diffusion layer forming composition 11 provides the formation of an n-type diffusion layer 12 in the desired site, without the formation of an unnecessary n-type diffusion layer on the mar surface or side face.

Accordingly, a side etching process for the removal of an unnecessary n-type diffusion layer formed on the side face was essential in a method for forming an n-type diffusion layer by the conventionally widely used gas-phase reaction method, but according to the producing method of the present invention, the side etching process becomes unnecessary, and consequently the process is simplified.

Further, the conventional producing method requires the conversion of an unnecessary n-type diffusion layer formed on the rear surface into a p⁺-type diffusion layer, and this conversion method employs a method involving applying a paste of aluminum, which is an element of Group XIII of the periodic table, on the n-type diffusion layer of the rear surface, followed by sintering to diffuse aluminum into the n-type diffusion layer which is thereby converted into a p⁺-type diffusion layer. Since an amount of aluminum greater than a certain level is required to achieve sufficient conversion into a p⁺-type diffusion layer and to form the high-density electric field layer of the p⁺-type diffusion layer in this method, it was necessary to form a thick aluminum layer. However, since the coefficient of the thermal expansion of aluminum is considerably different from the coefficient of the thermal expansion of the silicon which is used as a semiconductor substrate, such a difference results in generation of heavy internal stress in the silicon substrate during the sintering and cooling processes, which, contributes to warpage of the silicon substrate.

Such internal stress damages the grain boundary of crystals, resulting in the problem of an increase in power loss. Further, warpage readily leads to damage of cells in the conveyance of photovoltaic cells or in the connection with a copper line referred to as a tab line, during a module process. In recent years, advancement in slice processing techniques has led to thickness reduction of a silicon substrate, which results in a tendency for the cell to be more readily cracked.

However, since, according to the producing method of the present invention, no unnecessary n-type diffusion layer is formed on the mar surface, there is no need for the conversion, of an n-type diffusion layer into a p⁺-type diffusion layer, which consequently abolishes the necessity of making the aluminum layer thicker. As a result, it is possible to suppress the generation of internal stress in the silicon substrate or warpage. Accordingly, an increase in power loss, or damage to cells can be suppressed.

Further, when using the fabrication method of the present invention, the producing method of a p⁺-type diffusion layer (high-density electric field layer) 14 of the rear surface can employ any method without being limited to the method involving conversion of an n-type diffusion layer into a p-type diffusion layer using aluminum, and choices for the producing method are then broadened.

For example, it is preferable that the p-type diffusion layer forming composition 13 is applied to a rear side of a p-type semiconductor substrate 10 (i.e., the opposite surface to the surface to which the n-type diffusion layer forming composition is applied); and thermal diffusion treatment is carried out; thereby forming the high-density electric field layer 14 on the rear side. At this point a specific metal atom contained in the p-type diffusion layer forming composition diffuses into the p-type diffusion layer 14. This relaxes lattice distortion due to plastic deformation occurred in the region where the p-type impurity atom (for example, a boron atom) is diffused in high concentration, thereby inhibiting the occurrence of a defect. The specific metal atom diffused in the p-type diffusion layer is preferably contained in a concentration range of 1×10¹⁷ atoms/cm³ or higher at the surface of the p-type diffusion layer. From the aspect that diffusion of the p-type impurity atom is inhibited by decreasing the lattice defect, the concentration is more preferably in a range of 1×10¹⁷ atoms/cm³ to 1×10²⁰ atoms/cm³ so that the concentration does not become too high.

As will be described later, the material used for a surface electrode 20 of the rear surface is not limited to aluminum of Group XIII of the periodic table. For example, Ag (silver), Cu (copper) or the like may also be used, so the thickness of the surface electrode 20 of the rear surface can be further reduced as compared to the related art.

In FIG. 1(4), an antireflective film 16 is formed over the n-type diffusion layer 12. The antireflective film 16 is formed by using a known technique. For example, when the antireflective film 16 is a silicon nitride film, the antireflective film 16 is formed by a plasma CVD method using a mixed gas of SiH₄ and NH₃ as a raw material. At this time, hydrogen diffuses into crystals, and an orbit which does not contribute to bonding of silicon atoms, that is, a dangling bond binds to hydrogen, which inactivates a defect (hydrogen passivation).

More specifically, the antireflective film 16 is formed under the conditions of a mixed gas NH₃/SiH₃ flow ratio of 0.05 to 1.0, a reaction chamber pressure of 13.3 Pa (0.1 Torr) to 266.6 Pa (2 Torr), a film-forming temperature of 300° C. to 550° C., and a plasma discharge frequency of 100 kHz or higher.

In FIG. 1(5), a metal paste for a surface electrode is printed and applied on the antireflective film 16 of the front surface (light-receiving side) by a screen printing method, followed by drying to form a metal, paste layer for a surface electrode 17. The metal paste for a surface electrode contains (1) metal, particles and (2) glass particles as essential components, and optionally (3) a resin binder, (4) other additives, and the like.

Then, a rear surface electrode 20 is also formed on the p⁺-type diffusion layer (high-density electric field layer) 14 of the rear surface. As described, hereinbefore, the constituent material and forming method of the rear surface electrode 20 are not particularly limited in the present invention. For example, the rear surface electrode 20 may also be formed by applying the rear surface electrode paste containing a metal such as aluminum, silver or copper; followed by drying. In this case, a portion of the rear surface may also be provided with a silver paste for forming a silver electrode, for connection between cells in the module process.

In FIG. 1(6), electrodes are sintered to complete a photovoltaic cell. When the sintering is carried out at a temperature in the range of 600 to 900° C. for several seconds to several minutes, the front surface side undergoes melting of the antireflective film 16 which is an insulating film, due to the glass particles contained in the electrode-forming metal paste, and the silicon 10 surface is also partially melted, by which metal particles (for example, sliver particles) in the paste form a contact with the silicon substrate 10, followed by solidification. In this manner, electrical conduction is made between the formed surface electrode 18 and the silicon substrate 10. This process is called fire-through.

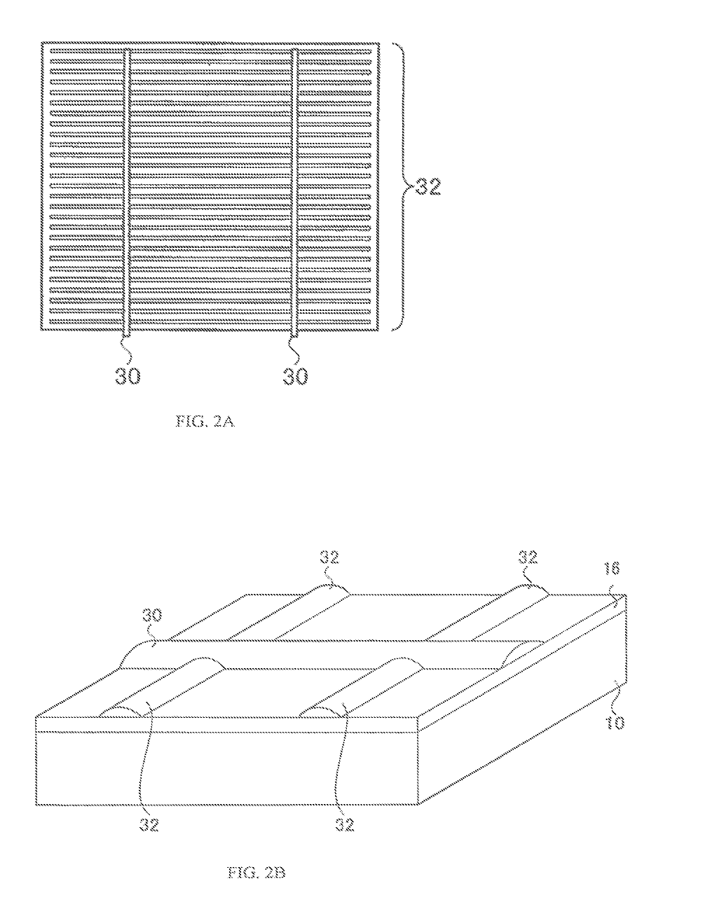

Hereinafter, the shape of the surface electrode 18 is described. The surface electrode 18 is made up of a bus bar electrode 30 and a finger electrode 32 intersecting the bus bar electrode 30. FIG. 2A is a plan view of, as seen from the front surface, a photovoltaic cell with a configuration where the surface electrode 18 is made up of the bus bar electrode 30 and the finger electrode 32 intersecting the bus bar electrode 30, and FIG. 2B is a partially enlarged perspective view of FIG. 2A.

The surface electrode 18 can be formed, for example, by the above-stated screen printing of a metal paste, or plating of electrode materials, deposition of electrode materials by electron beam heating under high vacuum, or the like. It is well known that the surface electrode 18 made up of the bus bar electrode 30 and the finger electrode 32 is typically used as an electrode for the light-receiving surface side, and a known method for the formation of the bus bar electrode and the finger electrode of the light-receiving surface side can be applied.

Although a photovoltaic cell having an n-type diffusion layer formed on the front surface, a p⁺-type diffusion layer formed on the rear surface, and a front surface electrode and a rear surface electrode disposed on the respective layers was described above, the use of the semiconductor substrate produced by using the impurity diffusion layer forming composition which enables patterning enables the production of a photovoltaic cell element having a selective emitter structure.

A photovoltaic cell element having a selective emitter structure for the purpose of a high efficiency is composed by including two n-type diffusion layers having different impurity concentrations and has a structure in which the region in the n-type diffusion layer immediately under the electrode has a high impurity concentration and the other region which is the light-receiving region has a low impurity concentration. The n-type impurity diffusion layer forming composition can be used also for forming a high concentration diffusion layer immediately under the electrode.

In a photovoltaic cell element having a selective emitter structure, there exists a high concentration region in which the n-type impurity concentration of the n⁺-type diffusion layer formed in use thermal diffusion treatment at a distance of 0.10 can to 1.0 μm in the depth direction of the p-type semiconductor substrate is 100×10²⁰ atoms/cm³ or higher. Preferably, the high concentration region exists at a distance of 0.12 μm to 1.0 μm in the depth direction. More preferably the high concentration region exists at a distance of 0.15 μm to 1.0 μm in the depth direction. Generally, the concentration of diffused impurity decreases from the surface layer of the substrate in the depth direction. For this reason, in cases where a high concentration region, exists in a depth in the above-mentioned range, even when the surface layer of the substrate is eroded by a glass component in the electrode forming material of the electrode formed on the n⁺-type diffusion layer, a good ohmic contact with the electrode can be obtained in a region having a sufficient impurity concentration.

The impurity concentration of the semiconductor substrate in the depth direction, as mentioned, can be measured by conducting by conducting a secondary ion mass spectrometry (SIMS analysis) by a conventional method using IMS-7F (manufactured by CAMECA CO., LTD.).

Further, in the photovoltaic cell element, when the sheet resistance at the surface of the n⁺-type diffusion layer is 20 Ω/sq. to 40 Ω/sq., the concentration gradient of the n-type impurity from the surface to 0.1 μm in the depth direction is preferably −9.00×10²¹ atoms/(cm³·μm), and more preferably −8.00×10²¹ atoms/(cm³·μm). When the concentration gradient of the n-type impurity from the surface to a depth of 0.1 μm is in the above-mentioned range, the carrier collection efficiency tends to be further improved.

The concentration gradient of the n-type impurity from the surface to a depth of 0.1 μm is calculated by dividing, by a distance of 0.1 μm, the difference of the n-type impurity concentration which is obtained by subtracting the n-type impurity concentration at the surface from the n-type impurity concentration at a depth 0.1 μm from the surface.

In a case using the n⁺-type diffusion layer forming composition to form an n⁺-type diffusion layer in which an impurity is diffused at a high concentration as mentioned above, the sheet resistance of the surface of the n⁺-type diffusion layer is preferably 20 Ω/sq. to 60 Ω/sq., and more preferably 20 Ω/sq. to 40 Ω/sq.

The sheet resistance can be measured, for example, by a four-point probe method using Low Resistivity Meter Loresta-EP MCP-T360 manufactured by Mitsubishi Chemical Corporation. In the present invention, the sheet resistances at 25 points are measured to obtain the arithmetic mean value thereof to evaluate the sheet resistance.

Further, the layer thickness of the n⁺-type diffusion layer (i.e., junction depth) is preferably in a range of 0.5 μm to 3 ∞m, and more preferably in a range of 0.6 μm to 2 μm.

The layer thickness of the n⁺-type diffusion layer (junction depth) is determined as a depth at which the impurity concentration which is measured in the depth direction of the semiconductor substrate is 1.00×10¹⁶ atoms/cm³ or less.

In a method for producing a photovoltaic cell element, in the region other than the n⁺-type diffusion layer having a high impurity concentration (hereinafter, also referred to as “first n-type diffusion layer”) in the silicon substrate, an n-type diffusion layer having a low impurity concentration (hereinafter, also referred to as “second, n-type diffusion layer”) is formed. Examples of a method of forming a second n-type diffusion layer include a method in which the n-type diffusion layer forming composition is provided to be subjected to a thermal diffusion treatment and a method in which a thermal treatment is conducted in an atmosphere containing an n-type impurity.

In a case the second n-type diffusion layer is formed by using an n-type diffusion layer forming composition. It is preferred that an n-type diffusion layer forming composition having a low impurity concentration be used. In a method of providing two n-type diffusion layer forming composition having different impurity concentrations, in a region where an electrode is to be formed, an n⁺-type diffusion layer is formed by an n-type diffusion layer forming composition having a high impurity concentration; and in a light-receiving region, an n-type diffusion layer can be formed by an n-type diffusion layer forming composition having a low impurity concentration.

In this case, the n⁺-type diffusion layer and the n-type diffusion layer may individually be formed by being subjected to a thermal diffusion treatment, and are preferably formed simultaneously in one thermal diffusion treatment.

On the other hand, the atmosphere containing an n-type impurity in a method of forming the second n-type diffusion layer by conducting a thermal treatment in an atmosphere containing an n-type impurity is not particularly restricted as long as it contains an n-type impurity. Examples thereof include a mixed gas atmosphere of phosphorus oxychloride (POCl₃), nitrogen and oxygen.

The thermal treatment condition is the same as the above.

In the second n-type diffusion layer, the sheet resistance of the surface thereof is preferably about 100 Ω/sq. The impurity concentration at the surface thereof is preferably in a range of 1.00×10¹⁸ atoms/cm³ to 1.00×10²⁰ atoms/cm³ and the layer thickness (junction depth) is preferably 0.2 μm to 0.3 μm. By this, recoupling of carriers generated by light irradiation can be inhibited, and the carriers can be efficiently collected in the first n-type diffusion layer.

On the other hand, the use a semiconductor substrate produced by using both an n-type impurity diffusion layer forming composition and a p-type impurity diffusion layer forming composition enables the production of a back-contact photovoltaic cell element.

A back-contact photovoltaic cell for the purpose of a high efficiency is composed by disposing n⁺-type diffusion layer and p⁺-type diffusion layer on a rear surface which is not a light-receiving surface alternately and forming an electrode on each impurity diffusion layer. The use a p-type diffusion layer forming composition enables to form a p⁺-type diffusion layer on the specific region selectively.

In a case the impurity diffusion layer forming composition is used for forming an impurity diffusion layer, the specific metal atom in the impurity diffusion layer forming composition, also diffuses into the impurity diffusion layer. Particularly in the region of the uppermost layer wherein a metal atom is diffused at a high concentration, a slight surface roughening occurs. This thought to be, for example, because the solubility of a silicon containing a specific metal atom to hydrogen fluoride improves.

For this reason, it becomes easy to identify the formed impurity diffusion layer, and occurrence of the displacement of the electrode and the impurity diffusion layer is inhibited when the electrode is formed.

This surface roughening is observed as a convex trough and the average depth thereof is in a range of 0.004 μm to 0.1 μm, which is considerably shallow and does not affect file power generation characteristics. Further, the surface roughening is about 0.004 μm to 0.1 μm when measured as the arithmetic mean roughness Ra.

The surface roughening can be observed by using a scanning electron microscope (SEM). The arithmetic mean roughness can be measured using Color 3D Laser Scanning Microscope VK-9700 (manufactured by KEYENCE CORPORATION) according to the JIS B0601 method.

### <Photovoltaic Cell>

The photovoltaic cell of the present invention includes at least one of the photovoltaic cell elements and is configured such that a wiring material is disposed on the electrode of the photovoltaic cell element. The photovoltaic cell may further be connected to plural photovoltaic cell elements via the wiring material as needed, and further, may be configured by being sealed by a sealing material.

The wiring material and the sealing material are not particularly restricted, and appropriately selected from those usually used in the art.

### EXAMPLES

Hereinafter, Examples in accordance with the present invention will be described in more detail, but the present invention is not limited thereto. Unless specifically indicated, “%” refers to “% by mass”.

### Example 1

Ten grams of P₂O₅—SiO₂—CaO glass (P₂O₅: 50%, SiO₂: 43%, CaO: 7%) powder whose particle shape was nearly spherical, whose average particle diameter was 1.0 μm and whose softening temperature was 700° C., 6.8 g of ethyl cellulose and 83.2 g of terpineol were mixed using an automatic mortar kneading machine and processed to a paste to prepare an n-type impurity diffusion layer forming composition.

Next, on the whole surface of the p-type silicon substrate, the prepared paste was applied by screen printing, dried at 150° C. for 10 minutes and then conducted a de-binder treatment at 400° C. for 3 minutes. Next, the resultant was subjected to a thermal treatment at 900° C. for 10 minutes in the air, and an n-type impurity atom was diffused into the silicon substrate to form an n-type diffusion layer thereby obtaining a semiconductor substrate having a p-type semiconductor layer and an n-type diffusion layer.

Subsequently, the glass layer remained on the surface of the silicon substrate was removed by hydrogen fluoride.

The sheet resistance of the surface on the side on which the n-type impurity diffusion layer forming composition was applied was 35 Ω/sq. On the surface, P (phosphorus) was diffused and an n-type diffusion layer was formed. The sheet resistance of the back surface was 1,000,000 Ω/sq. or higher, which was unmeasurable. It was determined that an n-type diffusion layer was not substantially formed.

The sheet resistance was determined by measuring at 25 points at 25° C. by a four-point probe method using Low Resistivity Meter Loresta-EP MCP-T360 manufactured by Mitsubishi Chemical Corporation, and calculating the arithmetic mean value thereof.

Elements other than the n-type impurity atom existing in the n-type diffusion layer were confirmed by a secondary ion mass spectrometry (SIMS analysis), and as a result, the content of Ca at the surface in the n-type diffusion layer was 1×10¹⁷ atoms/cm³.

The secondary ion mass spectrometry (SIMS analysis) was conducted using IMS-7F (manufactured by CAMECA CO., LTD.) by a conventional method.

### Example 2

The n-type diffusion layer was formed in the same manner as in Example 1 except that the thermal diffusion treatment time was 30 minutes to obtain a semiconductor substrate having a p-type semiconductor layer and an n-type diffusion layer.

The sheet resistance of the surface on the side on which the n-type impurity diffusion layer forming composition was applied was 24 Ω/sq. On the surface, P (phosphorus) was diffused and an n-type diffusion layer was formed. The sheet resistance of the back surface was 1,000,000 Ω/sq. or higher, which was immeasurable. It was determined that an n-type diffusion layer was not substantially formed.

The content of Ca at the surface in the n-type diffusion layer was 1×10¹⁹ atoms/cm³.

### Example 3

The n-type diffusion layer was formed in the same manner as in Example 1 except that P₂O₅—SiO₂—MgO glass (P₂O₅: 50%, SiO₂: 43%, MgO: 7%) powder whose panicle shape was nearly spherical, whose average particle diameter was 1.0 μm and whose softening temperature was 700° C. was used, to obtain a semiconductor substrate having a p-type semiconductor layer and an n-type diffusion layer.

The sheet resistance of the surface on the side on which the n-type impurity diffusion layer forming composition was applied was 30 Ω/sq. On the surface, P (phosphorus) was diffused and an n-type diffusion layer was formed. The sheet resistance of the back surface was 1,000,000 Ω/sq. or higher, which was unmeasurable. It was determined that an n-type diffusion layer was not substantially formed.

The content of Mg at the surface in the n-type diffusion layer was 1×10¹⁹ atoms/cm³).

### [Manufacturing of Photovoltaic Cell Element]

By using the semiconductor substrate obtained in example 1 to 3 on which the n-type diffusion layer was formed, photovoltaic cell elements were individually manufactured by forming an antireflection film on the light-receiving surface, forming a surface electrode on the surface region where an electrode was to be formed and forming a back surface electrode on the back surface individually by a conventional method.

All of the obtained photovoltaic cell elements had an improved conversion efficiency by 0.1% compared to a photovoltaic cell element in which an n-type diffusion layer was formed by a conventional gas-phase diffusion using phosphorus oxychloride.

### [Manufacturing of Photovoltaic Cell Element Having Selective Emitter Structure]

On the surface of the p-type silicon substrate, an n-type diffusion layer forming composition of Example 1 was applied in a finger shape in a width of 150 μm and in a bus bar shape in a width of 1.5 mm and dried at 150° C. for 10 minutes.

Next, the resultant was subjected to a thermal treatment at 900° C. for 10 minutes in the air, and an n-type impurity was diffused into the silicon substrate to form an n⁺-type diffusion layer (hereinafter, also referred to as “first n-type diffusion layer”) on the region where an electrode was to be formed. Next, the resultant was subjected to a thermal treatment at 830° C. for 10 minutes in the mixed gas atmosphere of phosphorus oxychloride (POCl₃), nitrogen and oxygen, and an n-type impurity was diffused into the silicon substrate to form a second n-type diffusion layer on the light-receiving region.

Subsequently, the glass layer remained on the surface of the silicon substrate was removed by hydrogen fluoride.

The average sheet resistance of the first n⁺-type diffusion layer (the first n-type diffusion layer) represented 35 Ω/sq., and the average sheet resistance office other surface of the n-type diffusion layer (the second n-type diffusion layer) represented 102 Ω/sq.

Elements other than the n-type impurity atom existing m the n-type diffusion layer were confirmed by a secondary ion mass spectrometry (SIMS analysis), and as a result, the content of Ca at the surface in the n-type diffusion layer was 1×10¹⁷ atoms/cm³.

For the region on which a first n-type diffusion layer (n-type diffusion layer) is formed mentioned above, a secondary ion mass spectrometry (SIMS analysis) by a conventional method using IMS-7F (manufactured by CAMECA CO., LTD.) was conducted to determine the concentration of a P (phosphorus) atom (n-type impurity atom) in the depth direction.

The n-type impurity concentration at a depth of 0.020 μm from the surface of n³⁰ -type diffusion layer (hereinafter, also referred to as “n-type impurity concentration at the surface”) was 1.01×10²¹ atoms/cm³ and the n-type impurity concentration at a depth of 0.1 μm was 1.46×10^{°}atoms/cm³. Accordingly, the concentration gradient of n-type impurity atoms from the surface to the depth of 0.1 μm was −8.64×10²¹ atoms/(cm³·μm).

In the n⁺-type diffusion layer, a region in which the n-type impurity concentration was 1.00×10²⁰ atoms/cm³ or higher was formed from the surface to a depth of 0.13 μm.

On the surface of the formed first n-type diffusion layer, a roughened convex trough was formed. The arithmetic mean, roughness Ra was measured using Color 3D Laser Scanning Microscope VK-9700 (manufactured by REVENGE CORPORATION) to obtain 0.05 μm.

The arithmetic mean roughness Ra was measured according to a method of J1S B0601. The object to be measured was on one triangle surface of a quadrangular pyramid whose height was about 5 μm and whose base was about 20 μm, which is a part of texture of the surface of the silicon substrate. This region is very small and the measurement length was 5 μm. Although the evaluation length may be 5 μm or longer, it is needed to remove the irregularity of the texture of the surface of the n⁺-type diffusion layer in this case. At the time of the measurement, measurement values were calibrated by using roughness standard specimen No. 178-605 manufactured by Mitutoyo Corporation or the like before the measurement.

In the same manner, for the region on which the second n-type diffusion layer was focused, the n-type impurity concentration in the depth direction was measured.

The n-type impurity concentration at the surface of the second n-type diffusion layer was 100×10²¹ atoms/cm³, and the n-type impurity concentration at a depth of 0.1 μm was 2.79×10¹⁸ atoms/cm³. Accordingly, the n-type impurity concentration gradient from the surface to the depth 0.1 μm was −9.97×10²¹ atoms/(cm³·μm).

In the second n-type diffusion layer, a region in which the n-type impurity concentration was 1.00×10²⁰ atoms/cm³ or higher was formed from the surface to a depth 0.02 μm.

By using the above-obtained silicon substrate on which the first and the second n-type diffusion layers were formed, a photovoltaic cell element was manufactured by forming an antireflection film on the surface, forming a surface electrode on the region where an electrode was formed and forming a back surface electrode on the back surface by a conventional method. The finger portion of the light-receiving surface electrode was formed in a width of 100 μm and in a width, of the bus bar portion of 1.1 mm. Concretely, the formation was conducted in a method in which, by using a screen printer provided with CCD camera-controlled positioning sysytem, the position of a region on which an electrode paste was to be applied and the position of a region on which a first n-type diffusion layer was formed were adjusted, and the electrode paste was applied, followed by a thermal treatment.

When comparing the region where an electrode was formed and the region of the first n-type diffusion layer by observing the portion where the light-receiving surface electrode was formed by a microscope in the above manner, it was confirmed that there was no displacement and the first n-type diffusion layer were wider with respect to the electrode in the both sides thereof respectively by a width of 25 μm at the finger portion.

The obtained photovoltaic cell, element had an improved optical conversion characteristics compared with a photovoltaic cell element not having a region where an electrode was formed in which a high concentration n-type diffusion layer was formed (selective emitter).

### Example 5

20 grams of B₂O₃—SiO₂—Na₂O glass powder (trade name: TMX-404, manufactured by Tokan Material Technology Co., Ltd.) whose particle shape was nearly spherical, whose average particle diameter was 4.9 μm and whose softening temperature was 561° C., 0.5 g of ethyl cellulose and 10 g of terpineol were mixed using an automatic mortar kneading machine and processed to a paste to prepare an p-type impurity diffusion layer forming composition.

Next, on the rear surface of the p-type silicon substrate on whose surface n-type diffusion layer was formed, the prepared paste was applied by sawn printing, dried at 150° C. for 10 minutes and then conducted a de-binder treatment at 400° C. for 3 minutes. Next, the resultant was subjected to a thermal treatment at 950° C. for 30 minutes in the air, and a p-type impurity atom was diffused into the silicon substrate to form a p⁺-type diffusion, layer thereby obtaining a semiconductor substrate.

Subsequently the glass layer remained on the surface of the silicon substrate was removed by hydrogen fluoride.

The sheet resistance of the surface on the side on which the p-type impurity diffusion layer forming composition was applied was 60 Ω/sq. On the surface, B (boron) was diffused and a p⁺-type diffusion layer was formed.

Elements other than the p-type impurity atom existing in the p⁺-type diffusion layer were confirmed by a secondary ion mass spectrometry (SIMS analysis), and as a result, the content of Na at the surface in the p⁺-type diffusion layer was 1×10¹⁷ atoms/cm³.

### Example 6

The p⁺-type diffusion layer was formed in the same manner as in Example 5 except that the thermal diffusion treatment at 1000° C. for 10 minutes to obtain a semiconductor substrate.

The sheet resistance of the surface on the side on which the p-type impurity diffusion layer forming composition was applied was 40 Ω/sq. On the surface, B (boron) was diffused and a p⁺-type diffusion layer was formed.

The content of Na at the surface in the p⁺-type diffusion, layer was 1×10^{·}atoms/cm³.

### Example 7

The p-type diffusion layer was formed in the same manner as in Example 5 except that B₂O₃—SiO₂—CaO glass powder (trade name: TMX-403, manufactured by Tokan Material Technology Co., Ltd.) whose particle shape was nearly spherical, whose average particle diameter was 5.1 μm and whose softening temperature was 808° C. was used, to obtain a semiconductor substrate.

The sheet resistance of the surface on the side on which the p-type impurity diffusion layer forming composition was applied was 65 Ω/sq. On the surface, B (boron) was diffused and a p⁺-type diffusion layer was formed.

The content of Ca at the surface in the p⁺-type diffusion layer was 1×10¹⁷ atoms/cm³.

### [Manufacturing of Photovoltaic Cell Element]

By using the semiconductor substrate obtained in example 5 to 7 on which the p⁺-type diffusion layer was formed, photovoltaic cell elements were individually manufactured by forming an antireflection film on the light-receiving surface, forming a surface electrode on the surface region where an electrode was to be formed and forming a back surface electrode on the back surface individually by a conventional method. All of the obtained photovoltaic cell elements had an improved conversion efficiency by 0.07% compared to a photovoltaic cell element obtained by using a conventional p-type diffusion layer forming composition contained boron compound.

### Example 8

A patterned p-type diffusion layer was formed in the same manner as in Example 1 except that, on the surface of the n-type silicon substrate, an p-type diffusion layer forming composition prepared in Example 5 was applied in pattern in a finger shape in a width of 150 μm and in a bus bar shape in a width of 1.5 mm.

When observed in SEM (×10,000), on the surface of the formed first p⁺-type diffusion layer, a roughened convex trough was formed. The arithmetic mean roughness Ra was measured to obtain 0.06 μm.

The sheet resistance of the surface of the p⁺-type impurity diffusion layer was 65 Ω/sq.

Elements other than the p-type impurity atom existing in the p⁺-type diffusion layer were confirmed by a secondary ion mass spectrometry (SIMS analysis), and as a result, the content of Na at the surface in the p⁺-type diffusion layer was 1×10¹⁷ atoms/cm³.

An electrode was formed on the formed p⁺-type diffusion layer in such a manner that the finger portion was formed in a width of 100 μm and in a width of the bus bar portion of 1.1 mm. Concretely, the formation of an electrode was conducted in a method in which, by using a screen printer provided with CCD camera-controlled positioning system, the position of a region on which an electrode paste was to be applied and the position of a region on which a p⁺-type diffusion layer was formed were adjusted, and the electrode paste was applied, followed by a thermal treatment.

When comparing the region where an electrode was formed and the region of the first p-type diffusion layer by observing by a microscope in the above manner, it was confirmed that there was no displacement and the p-type diffusion layer were wider with respect to the electrode in the both sides thereof respectively by a width of 25 μm.

### Comparative Example 1

The n-type diffusion layer was formed in the same manner as in Example 1 except that the n-type diffusion layer forming composition was prepared by using P₂O₃—SiO₂ glass powder containing 1% Fe as a glass powder, to obtain a semiconductor substrate.

The sheet resistance of the surface on the side on which the n-type diffusion layer forming composition was applied was 34 Ω/sq, On the surface, P (phosphorus) was diffused and an n-type diffusion layer was formed. The sheet resistance of the back surface was 1,000,000 Ω/sq, or higher, which was immeasurable, it was determined that an n-type diffusion layer was not substantially formed.

The content of Fe at the surface in the n-type diffusion layer was 1×10^{∫}atoms/cm³.

By using the above-obtained silicon substrate on which the n-type diffusion layer was formed, a photovoltaic cell element was manufactured by forming an antireflection film on the light-receiving surface, forming a surface electrode on the region where an electrode was to be formed and forming a back surface electrode on the back surface individually by a conventional method. The obtained photovoltaic cell had decreased optical conversion characteristics compared to a photovoltaic cell element in which an n-type diffusion layer was formed by a conventional gas-phase diffusion using phosphorus oxychloride.

### Comparative Example 2

The p⁺-type diffusion layer was formed in the same manner as in Example 5 except that the p-type diffusion layer forming composition was prepared by using B₂O₃—SiO₂ glass powder containing 1% Fe as a glass powder, to obtain a semiconductor substrate.

The sheet resistance of the surface on the side on which the p-type diffusion layer forming composition was applied was 63 Ω/sq. On the surface, B (boron) was diffused and a p⁺-type diffusion layer was formed. The sheet resistance of the back surface was 1,000,000 Ω/sq, or higher, which was unmeasurable. It was determined that a p-type diffusion layer was not substantially formed.

The content of Fe at the surface in the p⁺-type diffusion layer was 1×10¹⁷ atoms/cm³.

By using the above-obtained silicon substrate, a photovoltaic cell element was manufactured by forming an antireflection film on the light-receiving surface, forming a surface electrode on the region where an electrode was to be formed and forming a back surface electrode on the back surface individually by a conventional method. The obtained photovoltaic cell element had decreased optical conversion characteristics compared to a photovoltaic cell element obtained by using a conventional p-type diffusion layer forming composition contained boron compound.

The foregoing description of the embodiments of the present invention has been provided for the purposes of illustration and description. It is not intended to be exhaustive or to limit the present invention to the precise forms disclosed. Obviously, many modifications and variations will be apparent to practitioners skilled in the art. The embodiments were chosen and described in order to best explain the principles of the present invention and its practical applications, thereby enabling others skilled in the art to understand the present invention for various embodiments and with the various modifications as are suited to the particular use contemplated. It is intended that the scope of the present invention be defined by the following claims and their equivalents.

All publications, patent applications, and technical standards mentioned in this specification are herein incorporated by reference to the same extent as if each individual publication, patent application, or technical standard was specifically and individually indicated to be incorporated by reference.

What is claimed is:

1. A semiconductor substrate, comprising:
a semiconductor layer; and
a patterned impurity diffusion layer within the semiconductor layer, the patterned impurity diffusion layer containing at least one impurity selected from the group consisting of an n-type impurity and a p-type impurity, and containing at least one metallic impurity selected from the group consisting of K, Na, Li, Ba, Sr, Ca, Mg, Be, Zn, Pb, Cd, V, Sn, Zr, Mo, La, Nb, Ta, Y, Ti, Ge, Te, and Lu,
wherein the patterned impurity diffusion layer has an uppermost surface having a surface roughening with an arithmetic mean roughness which is measurably distinguished from portions of an uppermost surface of the semiconductor layer adjacent to the patterned impurity layer.

2. The semiconductor substrate of claim 1, wherein the content of the metallic atom at a surface of the impurity diffusion layer is 1×10¹⁷ atoms/cm³ or more.

3. The semiconductor substrate of claim 1, wherein the n-type impurity atom is at least one selected from P (phosphorus) or Sb (antimony).

4. The semiconductor substrate of claim 1, wherein the p-type impurity atom is at least one selected from B (boron) and Ga (gallium).

5. The semiconductor substrate of claim 1, wherein the impurity diffusion layer contains the n-type impurity atom and is formed by subjecting a glass powder to heat treatment, the glass powder being attached to at least one surface of the semiconductor layer, and the glass powder containing a substance including at least one kind of n-type impurity selected from P₂O₃, P₂O₅ or Sb₂O₃, and containing at least one kind of glass component material selected from SiO₂, K₂O, Na₂O, Li₂O, BaO, SrO, CaO, MgO, BeO, ZnO, PbO, CdO, V₂O₅, SnO, ZrO_{2,} or MoO₃.

6. The semiconductor substrate of claim 1, wherein the impurity diffusion layer contains the p-type impurity and is formed by subjecting a glass powder to heat treatment, the glass powder being attached to at least one surface of the semiconductor layer, and the glass powder containing a substance including at least one kind of p-type impurity selected horn B₂O₃ or Ga₂O₃, and including at least one kind of glass component material selected from SiO₂, K₂O, Na₂O, Li₂O, BaO, SrO, CaO, MgO, BeO, ZnO, PbO, CdO, V₂O₅, SnO, ZrO_{2,} or MoO₃.

7. A photovoltaic cell element, comprising the semiconductor substrate of claim 1 and an electrode disposed on the impurity diffusion layer.

8. A photovoltaic cell, comprising the photovoltaic cell element of claim 7 and a wiring material disposed on the electrode.

9. A method of producing the semiconductor substrate of claim 1, the method comprising:
attaching an impurity diffusion layer-forming composition containing a glass powder containing at least one impurity atom selected from the group consisting of an n-type impurity atom and a p-type impurity atom, and a dispersion medium, to at least one surface of a semiconductor layer; and
forming an impurity diffusion layer by subjecting the attached impurity diffusion layer-forming composition to thermal diffusion treatment.
